(19) United States
(12) Patent Application Publication
(10) Pub. No.: US 2025/0323278 A1
(43) Pub. Date: Oct. 16, 2025

(54) NEGATIVE ELECTRODE CURRENT COLLECTOR AND PREPARATION METHOD THEREFOR, AND LITHIUM-ION BATTERY

(71) Applicant: ADVANCED MATERIALS TECHNOLOGY (BEIJING) CO., LTD., Beijing (CN)

(72) Inventors: Yongwei LI, Beijing (CN); Xinsen SUN, Beijing (CN); Xiufeng GONG, Beijing (CN)

(73) Assignee: ADVANCED MATERIALS TECHNOLOGY (BEIJING) CO., LTD., Beijing (CN)

(21) Appl. No.: 19/245,953

(22) Filed: Jun. 23, 2025

Related U.S. Application Data
(63) Continuation of application No. PCT/CN2023/140407, filed on Dec. 20, 2023.

(30) Foreign Application Priority Data
Dec. 23, 2022 (CN) 202211665081.8

(51) Int. Cl. H01M 4/66; H01M 4/02; H01M 4/04; H01M 10/0525

(52) U.S. Cl. CPC H01M 4/667; H01M 4/0426; H01M 4/662; H01M 4/668; H01M 2004/021; H01M 2004/027; H01M 10/0525

(57) ABSTRACT

In a lithium-ion battery, a negative electrode current collector includes a barrier layer I, a conductive layer I, a polymer layer, a conductive layer II, and a barrier layer II in sequence. For the negative electrode current collector, barrier layer I and barrier layer II are continuous and dense film structures, which can prevent the conductive materials in conductive layer I and conductive layer II from alloying, improve the conductivity of the current collector, and replace traditional copper as a negative electrode current collector. It is suitable for industrial promotion with advantages of low production cost, good corrosion resistance, electrochemical stability, thin thickness, light weight, low conductivity, and high safety.

### CROSS-REFERENCE TO RELATED APPLICATIONS

The present application claims the benefit of priority to Chinese Patent Application No. 202211665081.8, filed with the China National Intellectual Property Administration on Dec. 23, 2022 and entitled “NEGATIVE ELECTRODE CURRENT COLLECTOR AND PREPARATION METHOD THEREFOR AND LITHIUM-ION BATTERY”, the entire content of which is incorporated herein by reference.

### TECHNICAL FIELD

The present application relates to the field of current collector technology, and specifically to a negative electrode current collector and a preparation method therefor and a lithium-ion battery.

### BACKGROUND

Lithium-ion batteries generally use aluminum as the metal material for the positive electrode current collector and copper for the negative electrode current collector. This is because metallic aluminum has a high oxidation potential, and the size of the octahedral voids in its crystal lattice is similar to that of lithium, making it very easy for metallic aluminum to react with lithium to form alloys such as LiAl, Li₃Al₂, and Li₄Al₃. These reactions consume a large amount of Li⁺ and destroy the structure and morphology of the aluminum itself. Therefore, aluminum can be used as a current collector for the positive electrode of lithium-ion batteries, but cannot be used as a current collector for the negative electrode of lithium-ion batteries. During the battery charging and discharging process, Copper (Cu) exhibits a small lithium intercalation capacity while maintaining the stability of its structure and electrochemical properties, so it can be used as a current collector for the negative electrode of ion batteries.

As lithium-ion battery technology continues to develop, market demand has placed increasingly higher requirements on the energy density and weight of lithium-ion batteries. As a result, future current collectors of lithium-ion batteries are expected to evolve toward being thinner, lighter, highly conductive, and exhibiting excellent chemical and electrochemical stability. Simple copper and aluminum foils can no longer meet market demand, leading to the development of composite current collectors. However, the current composite current collectors generally have drawbacks such as large mass, low mechanical strength, easy detachment of the conductive layer, susceptibility to corrosion by the electrolyte, and low conductivity.

Therefore, it is urgent to provide a negative electrode current collector and a preparation method therefor that offer advantages such as corrosion resistance, electrochemical stability, thin thickness, light weight, and high conductivity.

### SUMMARY

The purpose of this application is to overcome the drawbacks associated with negative electrode current collector in the prior art such as large mass, low mechanical strength, easy detachment of conductive layer, susceptibility to corrosion by the electrolyte and high resistivity, and to provide a negative electrode current collector and a preparation method therefor and lithium-ion battery.

In order to achieve the above-mentioned purpose, in a first aspect, the present application provides a negative electrode current collector, which includes a barrier layer I, a conductive layer I, a polymer layer, a conductive layer II, and a barrier layer II in sequence.

In a second aspect, the present application provides a method for preparing a negative electrode current collector, in which the method includes preparing a conductive layer I and a conductive layer II on the upper surface and the lower surface of a polymer layer respectively, and subsequently preparing a barrier layer I on the conductive layer I and a barrier layer II on the conductive layer II.

In a third aspect, the present application provides a lithium-ion battery including a negative electrode current collector described in the first aspect of the present application.

Through the above technical solutions, the beneficial technical effects achieved by this application are as follows:
1) The negative electrode current collector provided in this application can replace the traditional copper foil as a negative electrode current collector, saving copper resources and costs while improving safety;
2) The negative electrode current collector provided in the present application, by arranging an intermediate layer I and an intermediate layer II, can mitigate the galvanic corrosion tendency and alloying degree between copper and aluminum; and
3) The negative electrode current collector provided in the present application, by arranging a barrier layer I and a barrier layer II, can block the formation of Li—Al alloy and improve the conductivity of the negative electrode current collector.

### BRIEF DESCRIPTION OF DRAWINGS

FIG. 1 is a first structural schematic diagram of the negative electrode current collector described in this application;

FIG. 2 is a second structural schematic diagram of the negative electrode current collector described in this application;

FIG. 3 is a third structural schematic diagram of the negative electrode current collector described in this application; and

FIG. 4 is a cross-sectional TEM image of the negative electrode current collector obtained in Embodiment 2.

### REFERENCE NUMERALS

1 Polymer layer; 2 Conductive layer I; 3 Conductive layer II; 4 Barrier layer I; 5 Barrier layer II; 6 Intermediate layer I; 7 Intermediate layer II; 8 Bonding layer I; 9 Bonding layer II.

### DETAILED DESCRIPTION OF THE EMBODIMENTS

The endpoints and any values of the range disclosed herein are not limited to the exact range or value, which should be understood to include values close to these ranges or values. For numerical ranges, one or more new numerical ranges may be obtained by combining the endpoint values of each range, between the endpoint values of each range and individual point values, and between individual point values, which shall be deemed to be specifically disclosed herein.

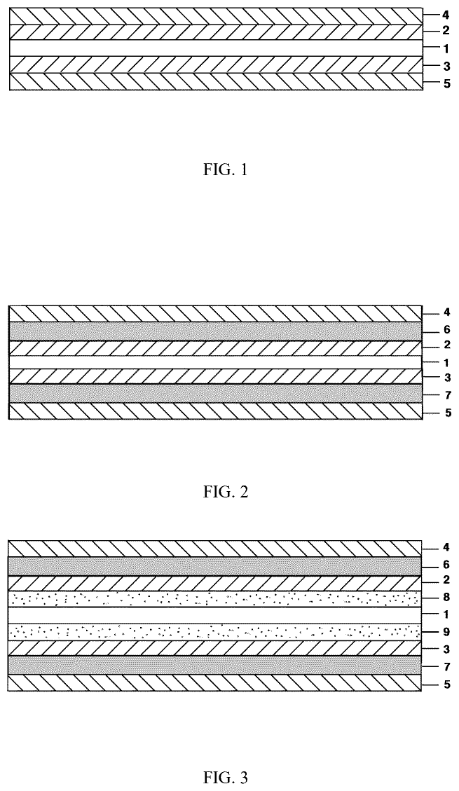

In a first aspect, the present application provides a negative electrode current collector, as shown in FIG. 1, which includes a barrier layer I 4, a conductive layer I 2, a polymer layer 1, a conductive layer II 3, and a barrier layer II 5 in sequence.

Specifically, in the present application, the barrier layer I 4 and the barrier layer II 5 are continuous and dense thin film structures, which can prevent alloying of conductive materials in the conductive layer I 2 and the conductive layer II 3 and improve the conductivity of the current collector.

In an embodiment, the materials of the barrier layer I and the barrier layer II are different from those of the conductive layer I and the conductive layer II.

In a preferred embodiment, the materials of the barrier layer I 4 and the barrier layer II 5 are independently selected from a single metal I or an alloy I, in which the single metal I is selected from one of a group consisted of aluminum, copper, nickel, iron, titanium, silver, gold, cobalt, chromium, molybdenum, and tungsten; preferably, the single metal I is selected from one of a group consisted of aluminum, copper, nickel, iron, titanium, silver, gold, cobalt, chromium, molybdenum, and tungsten with a purity of ≥98 wt %, preferably 99-100 wt %, in which the metal in the alloy I is selected from at least one of a group consisted of aluminum, copper, nickel, iron, titanium, silver, gold, cobalt, chromium, molybdenum, and tungsten, and the alloy I also includes an optional non-metal that is selected from at least one of a group consisted of carbon, nitrogen, and silicon. Preferably, the alloy I is selected from at least one of a group consisted of copper-aluminum alloy, copper-nickel alloy, copper-zinc alloy, and copper-tin alloy.

In a preferred embodiment, thicknesses of the barrier layer I 4 and the barrier layer II 5 are individually selected from 1-1500 nm, such as 1 nm, 10 nm, 100 nm, 500 nm, 800 nm, 1000 nm, 1200 nm, 1400 nm, 1500 nm, or any value between the aforementioned values, preferably 10-1000 nm.

In the present application, the barrier layer serves to block the exposure of aluminum (Al) at the negative side and has a conductive effect. The barrier layer of the present application is a continuous and dense film. The barrier layer cannot be too thin; otherwise, interdiffusion with the conductive layer may occur in a short period (a few days or weeks), exposing Al and losing its intended function. The barrier layer cannot be too thick; otherwise, process costs may be increased and material utilization efficiency impacted. Therefore, the thickness of the barrier layer is preferably 10-1000 nm, more preferably 30-800 nm.

In a preferred embodiment, bonding forces between the barrier layer I 4 and the conductive layer I 2 and between the conductive layer II 3 and the barrier layer II 5 are both ≥0.5 N/15 mm, such as 0.5 N/15 mm, 1 N/15 mm, 2 N/15 mm, 2.5 N/15 mm, 3 N/15 mm, 4 N/15 mm, 6 N/15 mm, 8 N/15 mm, 10 N/15 mm, 20 N/15 mm, or any value between the above values.

Specifically, in this application, the bonding forces between the barrier layer I 4 and the conductive layer I 2 and between the conductive layer II 3 and the barrier layer II 5 are tested using a universal tensile machine. For specific test methods, see the National Standard of the People's Republic of China GB/T 2792-2014 (Test Method for Peel Strength of Adhesive Tape).

In a preferred embodiment, the materials of the conductive layer I 2 and the conductive layer II 3 are independently selected from a single metal II or an alloy II, in which the single metal II is selected from one of a group consisted of aluminum, copper, nickel, iron, titanium, silver, gold, cobalt, chromium, molybdenum, and tungsten; preferably, the single metal II is selected from one of a group consisted of aluminum, copper, nickel, iron, titanium, silver, gold, cobalt, chromium, molybdenum, and tungsten with a purity of ≥98 wt %, preferably 99-100 wt %, in which the metal in the alloy II is selected from at least one of a group consisted of aluminum, copper, nickel, iron, titanium, silver, gold, cobalt, chromium, molybdenum, tungsten, manganese, magnesium, and zinc, and the alloy II also includes an optional non-metal that is selected from at least one of a group consisted of carbon, nitrogen, and silicon. Preferably, the alloy II is selected from at least one of a group consisted of aluminum-copper alloy, aluminum-manganese alloy, aluminum-silicon alloy, aluminum-magnesium alloy, aluminum-magnesium-silicon alloy, and aluminum-zinc alloy.

In a preferred embodiment, thicknesses of the conductive layer I 2 and the conductive layer II 3 are independently selected from 0.1-2 μm, such as 0.1 μm, 0.2 μm, 0.3 μm, 0.5 μm, 0.8 μm, 1 μm, 1.2 μm, 1.5 μm, 1.8 μm, 2 μm, or any value between the aforementioned values, preferably 0.2-1.5 μm.

In the present application, the conductive layer is a continuous film and has a conductive effect. The conductive layer cannot be too thin; otherwise, the pronounced size effect of the metal film will lead to high resistivity, affecting the internal resistance of the battery cell. The conductive layer cannot be too thick; otherwise, process costs may be increased and material utilization efficiency impacted. Therefore, the thickness of the conductive layer is preferably 0.2-1.5 μm. In a preferred embodiment, bonding forces between the conductive layer I 2 and the polymer layer 1 and between the polymer layer 1 and the conductive layer II 3 are both ≥0.5 N/15 mm, such as 0.5 N/15 mm, 1 N/15 mm, 2 N/15 mm, 2.5 N/15 mm, 3 N/15 mm, 4 N/15 mm, 6 N/15 mm, 8 N/15 mm, 10 N/15 mm, 20 N/15 mm, or any value between the above values.

Specifically, in this application, the bonding forces between the conductive layer I 2 and the polymer layer 1 and between the polymer layer and the conductive layer II are tested using a universal tensile machine. For specific test methods, see the National Standard of the People's Republic of China GB/T 2792-2014 (Test Method for Peel Strength of Adhesive Tape).

In a preferred embodiment, the resistivity of the conductive layer I 2 and the conductive layer II 3 is ≤8μΩ·cm, such as 1μΩ·cm, 2μΩ·cm, 3μΩ·cm, 4μΩ·cm, 5 μΩ·cm, 6 μΩ·cm, 7 μΩ·cm, 8 μΩ·cm, or any value between the above values, preferably 2-5 μΩ·cm. In this application, the resistivity test method refers to ASTM F390 (Standard Test Method for Sheet Resistance of Thin Metallic Films With a Collinear Four-Probe Array) in the United States.

In a preferred embodiment, the material of the polymer layer 1 is selected from at least one of a group consisted of acrylonitrile-butadiene-styrene copolymer (ABS), polyethylene terephthalate (PET), polybutylene terephthalate (PBT), poly(p-phenylene terephthalamide) (PPTA), polyimide (PI), polyamide (PA), polyethylene (PE), polystyrene (PS), polyvinylidene fluoride (PVDF), polyvinyl chloride (PVC), polytetrafluoroethylene (PTFE), poly(p-phenylene-ethynylene) (PPE), polypropylene (PP), polycarbonate (PC), polyoxymethylene (POM), epoxy resin, and phenolic resin.

In a preferred embodiment, the thickness of the polymer layer 1 is 1-15 μm, preferably 1-10 μm.

In the present application, reducing the thickness of the polymer layer can increase the energy density of the battery, but an excessively thin polymer layer is prone to breakage during the processing of the electrode sheet. The inventors of the present application have found through research that when the thickness of the polymer layer is within the above-mentioned limited range, the processing performance and electrical properties of the negative electrode current collector are better.

In a preferred embodiment, the tensile strength of the polymer layer 1 material is ≥150 MPa, such as 150 MPa, 180 MPa, 200 MPa, 250 MPa, 300 MPa, 400 MPa, 500 MPa, 600 MPa, or any value between the above values, preferably 150-400 MPa. Specifically, in the present application, the polymer layer is the substrate of the negative electrode current collector and mainly plays a supporting role, which can ensure the mechanical strength of the composite current collector and extend its service life. In this application, the tensile strength test refers to China's HG/T 2580-2008 (Determination of Tensile Strength and Elongation at Break of Rubber or Plastics Coated Fabrics).

In a preferred embodiment, the heat shrinkage rate of the polymer layer 1 material after being treated at 150° C. for 30 minutes is ≤3%, preferably 0.5%, 1%, 1.5%, 2%, 2.5%, 3%, or any value between the above values. Specifically, the test of the heat shrinkage after treatment at 150° C. for 30 minutes refers to ASTM D-1204 (Test Method for Linear Dimensional Changes of Nonrigid Thermoplastic Sheeting or Film at Elevated Temperature) specified by the American Society for Testing and Materials.

In a preferred embodiment, the barrier layer I 4 and the barrier layer II 5 are made of the same material, and the conductive layer I 2 and the conductive layer II 3 are made of the same material.

In a preferred embodiment, as shown in FIG. 2, the negative electrode current collector further includes an intermediate layer I 6 and an intermediate layer II 7, in which the intermediate layer I 6 is arranged between a barrier layer I 4 and a conductive layer I 2, and the intermediate layer II 7 is arranged between a barrier layer II 5 and a conductive layer II 3.

That is, in the present application, the structure of the negative electrode current collector can be barrier layer I-intermediate layer I-conductive layer I-polymer layer-conductive layer II-intermediate layer II-barrier layer II, specifically including a barrier layer I, an intermediate layer I, a conductive layer I, a polymer layer, a conductive layer II, an intermediate layer II, and a barrier layer II in sequence. Specifically, in the present application, the intermediate layer I and the intermediate layer II can mitigate the galvanic corrosion tendency and alloying degree between copper and aluminum to provide stability for lithium-ion batteries.

In a preferred embodiment, the materials of the intermediate layer I 6 and the intermediate layer II 7 are independently selected from a single metal III, an alloy III, an oxide semiconductor, or a conductive compound.

Specifically, the single metal III is selected from one of a group consisted of Cu, Cr, Ta, Zn, Cd, In, Tl, Mn, Co, Mo, Fe, Sn, Ge, Bi, Sb, Re, Ti, V, Ni, Nb, and Tc, preferably one of a group consisted of Ti, V, Cr, Mn, Fe, Co, Ni, and Cu;

Specifically, the metal in the alloy III is selected from at least one of a group consisted of Cu, Cr, Ta, Zn, Cd, In, Tl, Mn, Co, Mo, Fe, Sn, Ge, Bi, Sb, Re, Ti, V, Ni, Nb, and Tc, preferably at least one of a group consisted of Ti, V, Cr, Mn, Fe, Co, Ni, and Cu;

Specifically, the oxide semiconductor is selected from at least one of a group consisted of Cu₂O, ZnO, SnO₂, Fe₂O₃, TiO₂, ZrO₂, Co₂O₃, WO₃, In₂O₃, Al₂O₃, and Fe₃O₄;

Specifically, the conductive compound is selected from at least one of a group consisted of TiB₂, TiC, TiN, ZrB₂, ZrC, ZrN, VB2, VC, VN, NbB₂, NbC, NbN, TaB₂, TaC, CrB₂, Cr₃C₂, CrN, Mo₂C, Mo₂B₅, W₂B₅, WC, and LaB₆.

In a preferred embodiment, the intermediate layer I and the intermediate layer II are independently at least one of a group consisted of nickel, nickel-based alloy, copper-based alloy, and titanium nitride, preferably titanium nitride.

In a preferred embodiment, thicknesses of the intermediate layer I 6 and the intermediate layer II 7 are independently 1-1000 nm, such as 1 nm, 10 nm, 100 nm, 200 nm, 300 nm, 400 nm, 500 nm, 600 nm, 700 nm, 800 nm, 900 nm, 1000 nm, or any value between the above values, preferably 5-500 nm. Specifically, in the present application, when the thicknesses of the intermediate layer I 6 and the intermediate layer II 7 are within the above-mentioned limited range, the corrosion resistance of the negative electrode current collector can be further improved and the alloying degree of the conductive layer can be reduced.

In a preferred embodiment, as shown in FIG. 3, the negative electrode current collector further includes a bonding layer I 8 and a bonding layer II 9, in which the bonding layer I 8 is arranged between the conductive layer I 2 and the polymer layer 1 for connecting the conductive layer I 2 and the polymer layer 1; and the bonding layer II 9 is arranged between the conductive layer II 3 and the polymer layer 1 for connecting the conductive layer II 3 and the polymer layer 1.

That is, in the present application, the structure of the negative electrode current collector can be barrier layer I-intermediate layer I-conductive layer I-bonding layer I-polymer layer-bonding layer II-conductive layer II-intermediate layer II-barrier layer II, specifically including a barrier layer I, an intermediate layer I, a conductive layer I, a bonding layer I, a polymer layer, a bonding layer II, a conductive layer II, an intermediate layer II, and a barrier layer II in sequence.

In a preferred embodiment, the materials of the bonding layer I 8 and the bonding layer II 9 are independently selected from at least one of a group consisted of ethyl cellulose, methylene succinic acid, styrene, carboxymethyl cellulose, guanidinoacetic acid, isocyanate, polyurethane, chitosan, polycaprolactone, and styrene butadiene latex, and optionally selected from at least one of a group consisted of nano-silicon dioxide, nano-aluminum oxide, and graphene oxide.

In a preferred embodiment, thicknesses of the bonding layer I 8 and the bonding layer II 9 are individually selected from 0.2-3 μm, such as 0.2 μm, 0.8 μm, 1 μm, 2 μm, 3 μm, or any value between the aforementioned values, preferably 0.5-1 μm.

In a preferred embodiment, the intermediate layer I 6 and the intermediate layer II 7 are made of the same material, and the bonding layer I 8 and the bonding layer II 9 are made of the same material.

Specifically, the lithium-ion battery prepared by using the negative electrode current collector provided in this application has a better cycle life, smaller polarization, less tendency to be corroded by the battery electrolyte, and higher gravimetric energy density. This changes the traditional view that aluminum can only be used as a positive electrode current collector, and represents a significant innovation and transformation in the current collector structure of lithium-ion batteries, which is of great significance.

In a preferred embodiment, the corrosion rate of the negative electrode current collector is ≤0.5 mm/a. Specifically, in this application, the test method for the corrosion resistance of the negative electrode current collector is: using a three-electrode system under room temperature conditions, with a negative electrode current collector as a working electrode, a platinum electrode as a counter electrode, and a non-mercury ion electrode as a reference electrode; preparing an electrolyte consisting of a 1 mol/L lithium hexafluorophosphate organic solution (with a mass ratio of diethyl carbonate (DEC), dimethyl carbonate (DMC), and ethylene carbonate (EC) of 1:1:1); measuring the Tafel curve of the negative electrode current collector using an electrochemical workstation; using a traditional copper-aluminum foil current collector as a comparative sample; and listing the corrosion rates of both the negative electrode current collector and the traditional copper-aluminum foil current collector in the table.

In a second aspect, the present application provides a method for preparing a negative electrode current collector, in which the method includes: preparing a conductive layer I and a conductive layer II on the upper surface and the lower surface of a polymer layer respectively, and subsequently preparing a barrier layer I on the conductive layer I and a barrier layer II on the conductive layer II.

In a preferred embodiment, the method includes: preparing, by evaporation, the conductive layer I and the conductive layer II on the upper surface and the lower surface of the polymer layer respectively, and subsequently preparing, by evaporation or sputtering, the barrier layer I on the conductive layer I and the barrier layer II on the conductive layer II.

In a preferred embodiment, before preparing, by evaporation, the conductive layer I and the conductive layer II on the upper surface and the lower surface of the polymer layer 1, prepare, by coating, a bonding layer I and a bonding layer II on the upper surface and the lower surface of the polymer layer 1 respectively.

In a preferred embodiment, before preparing, by evaporation or sputtering, the barrier layer I and the barrier layer II on the conductive layer I and the conductive layer II, prepare, by magnetron sputtering, reactive sputtering, or activated reactive evaporation, an intermediate layer I on the conductive layer I and an intermediate layer II on the conductive layer II.

In a preferred embodiment, the evaporation is a vacuum evaporation, and operating conditions of the vacuum evaporation include: a vacuum degree higher than 10⁻³ Pa; a cold roller temperature of −25° C. to 35° C.; an ES distance≥50 mm; and an evaporation temperature≥800° C.

In a preferred embodiment, operating conditions of the magnetron sputtering include: a vacuum degree higher than 10-3 Pa; a main roller temperature of −25° C. to +35° C.; a main roller travel speed of less than 20 m/min; and a sputtering power of less than 20 kW.

In a preferred embodiment, operating conditions of the activated reaction evaporation include: a vacuum degree higher than 10-³ Pa; a cold roller temperature of −25° C. to 35° C.; an ES distance≥50 mm; and an evaporation temperature≥400° C.

The vacuum degree indicates the degree of gas rarefaction under vacuum conditions; a lower value corresponds to a thinner gas presence and a higher degree of vacuum.

In this application, the ES distance refers to the distance between the evaporation source and the substrate.

The evaporation source refers to a conductive metal material that is heated and vaporized in a vacuum evaporation chamber. The substrate refers to a pre-evaporated film material, such as a polymer film.

In this application, when the intermediate layer I and the intermediate layer II are selected as titanium nitride, the preparation method of titanium nitride is activated reactive evaporation (ARE), that is, during the vacuum deposition coating process, a certain amount of active reaction gas (such as N₂) that reacts with metal vapor is introduced into the vacuum chamber, and various discharge methods are used to activate and ionize metal vapor and reaction gas molecules/atoms to promote their chemical reaction and to obtain a compound coating on the surface of the workpiece.

The operation of the activated reaction evaporation can be performed as follows:

Vacuum while baking and degassing the aluminum foil substrate to maintain the vacuum degree before evaporation at 10-³ Pa or higher. Turn on the power of the electron gun to melt and degas the evaporation material titanium (Ti), fill the reaction gas N₂ through a needle valve, and open the baffle to obtain a compound coating on the aluminum foil substrate.

In a third aspect, the present application provides a lithium-ion battery including a negative electrode current collector described in the first aspect of the present application.

In order to further understand the present application, the technical solutions in the embodiments of the present application will be clearly and completely described below with reference to the embodiments. Obviously, the embodiments described are only a part of the embodiments of the present application. All other embodiments, derived by those of ordinary skill in the art without departing from the scope of the present application are intended to be included within the protective scope of this application.

Unless otherwise specified, the reagents involved in the embodiments of this application are all commercially available products and can be purchased through commercial channels.

Some embodiments and comparative examples are listed below.

Thickness: GB/T 11378-2005 (Metallic Coatings-Measurement of Coating Thickness-Profilometer Method).

Sheet resistance/resistivity: ASTM F390 (Standard Test Method for Sheet Resistance of Thin Metallic Films With a Collinear Four-Probe Array in the United States.

Bonding force: GB/T 2792-2014 (Measurement of Peel Adhesion Properties for Adhesive Tapes).

Mechanical properties: HG/T 2580-2008 (Determination of Tensile Strength and Elongation at Break of Rubber or Plastics Coated Fabrics).

Wetting tension: GB/T 22638.4-2016 (Test Method for Aluminum Foil—Part 4: Measurement of Surface Wetting Tension)

Heat shrinkage: (GB/T 12027-2004 Plastic Film and Sheet Heating Dimensional Change Rate Test Method)

The test method for the corrosion resistance of the negative electrode current collector is: using a three-electrode system under room temperature conditions, with a negative electrode current collector as a working electrode, a platinum electrode as a counter electrode, and a non-mercury ion electrode as a reference electrode; preparing an electrolyte consisting of a 1 mol/L lithium hexafluorophosphate organic solution (with a mass ratio of diethyl carbonate (DEC), dimethyl carbonate (DMC), and ethylene carbonate (EC) of 1:1:1); using an electrochemical workstation to generate the Tafel curve; and calculating the corrosion resistance based on the Tafel curve.

In the present application, corrosion resistance is characterized by a corrosion rate. The corrosion rate of the negative electrode composite current collector in this application is ≤0.1 mm/a.

Preparation method of battery cell: coating the negative electrode active material onto the surface of the composite current collector and drying to form a negative electrode roll; calendaring and die-cutting to prepare compacted positive and negative electrode sheets and stacking using a Z-fold lamination machine; tab welding, and packaging to form a pre-filled cell; filling with electrolyte, aging, and performing hot-press formation to activate the cell; and finally, conducting a second aging process to complete the battery cell by final sealing.

### Embodiment 1

First, 1 μm of metal Al is vacuum-deposited simultaneously on the upper and lower surfaces of 6 μm PET, followed by the deposition of 300 nm of Cu on the Al surface.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 2

First, 1 μm of metal Al is vacuum-deposited simultaneously on the upper and lower surfaces of 6 μm PET, followed by the deposition of 800 nm of metal Cu on the Al surface.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

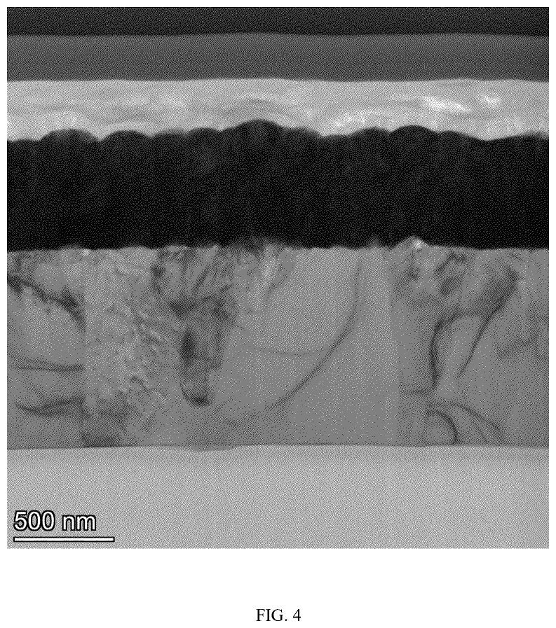

FIG. 4 is a cross-sectional TEM image of the negative electrode current collector obtained in Embodiment 2. It can be seen from FIG. 4 that the barrier layer thickness is dense and continuous enough to prevent the reaction between Li and Al, so that this structural material can be applied to the negative side.

### Embodiment 3

First, 1 μm of metal Al is vacuum-deposited simultaneously on the upper and lower surfaces of 6 μm PET, then 30 nm of metal Ni is deposited respectively on the upper and lower surfaces of Al by magnetron sputtering, and 300 nm of metal Cu is vacuum-deposited simultaneously on the upper and lower surfaces of metal Ni.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 4

First, 1 μm of metal Al is vacuum-deposited simultaneously on the upper and lower surfaces of 6 μm PET, then 30 nm of metal Ni is deposited respectively on the upper and lower surfaces of Al by magnetron sputtering, and 800 nm of metal Cu is vacuum-deposited simultaneously on the upper and lower surfaces of metal Ni.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 5

First, 1 μm of metal Al is vacuum-deposited simultaneously on the upper and lower surfaces of 6 μm PET, then 30 nm of metal compound TiN is deposited respectively on the upper and lower surfaces of Al by activated reactive evaporation (ARE), and 300 nm of metal Cu is vacuum-deposited simultaneously on the upper and lower surfaces of metal compound TiN.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 6

First, 1 μm of metal Al is vacuum-deposited simultaneously on the upper and lower surfaces of 6 μm PET, then 30 nm of metal compound TiN is deposited respectively on the upper and lower surfaces of Al by activated reactive evaporation (ARE), and 800 nm of metal Cu is vacuum-deposited simultaneously on the upper and lower surfaces of metal compound TiN.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 7

First, 1 μm of nano-silicon dioxide modified itaconic acid is respectively applied to the upper and lower surfaces of 6 μm PET using a coating machine. After drying, 1 μm of metal Al is vacuum-deposited simultaneously on the surface of the bonding layer, followed by the deposition of 300 nm of metal Cu on the Al surface.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 8

First, 1 μm of nano-silicon dioxide modified itaconic acid is respectively applied to the upper and lower surfaces of 6 μm PET using a coating machine. After drying, 1 μm of metal Al is vacuum-deposited simultaneously on the surface of the bonding layer, followed by the deposition of 800 nm of metal Cu on the Al surface.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 9

First, 1 μm of nano-silicon dioxide modified itaconic acid is respectively applied to the upper and lower surfaces of 6 μm PET using a coating machine. After drying, 1 μm of metal Al is vacuum-deposited simultaneously on the surface of the bonding layer, then 30 nm of metal Ni is deposited on the surface of Al by magnetron sputtering, and then 300 nm of metal Cu is deposited simultaneously on the surface of metal Ni.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 10

First, 1 μm of nano-silicon dioxide modified itaconic acid is respectively applied to the upper and lower surfaces of 6 μm PET using a coating machine. After drying, 1 μm of metal Al is vacuum-deposited simultaneously on the surface of the bonding layer, then 30 nm of metal Ni is deposited on the surface of Al by magnetron sputtering, and then 800 nm of metal Cu is deposited simultaneously on the surface of metal Ni.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 11

First, 1 μm of nano-silicon dioxide modified itaconic acid is respectively applied to the upper and lower surfaces of 6 μm PET using a coating machine. After drying, 1 μm of metal Al is vacuum-deposited simultaneously on the surface of the bonding layer, then 30 nm of metal compound TiN is deposited on the surface of Al by activated reactive evaporation (ARE), and then 300 nm of metal Cu is deposited simultaneously on the surface of metal compound TiN.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### Embodiment 12

First, 1 μm of nano-silicon dioxide modified itaconic acid is respectively applied to the upper and lower surfaces of 6 μm PET using a coating machine. After drying, 1 μm of metal Al is vacuum-deposited simultaneously on the surface of the bonding layer, then 30 nm of metal compound TiN is deposited on the surface of Al by activated reactive evaporation (ARE), and then 800 nm of metal Cu is deposited simultaneously on the surface of metal compound TiN.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

### COMPARATIVE EXAMPLE

1 μm metal Al is directly evaporated on the upper and lower surfaces of 6 μm PET respectively.

The composite current collector after film formation is used as the negative electrode current collector, and a battery cell is prepared through the above process. The performance of the battery cell is tested, and the electrochemical properties of the composite current collector material are characterized. The test results are shown in Tables 1 and 2.

TABLE 1
Performance of composite current collector materials

| | | | | | | | Corrosion |
|---|---|---|---|---|---|---|---|
| | Sheet | Bond- | | | | | rate of |
| | resis- | ing | Tensile | | Heat | | composite |
| | tance | force | strength | | shrinkage | | current |
| | (mΩ/ | (N/15 | (MPa) | | (%) | | collector |
| No. | sq) | mm) | MD | TD | MD | TD | (mm/a) |
| Embodiment 1 | 26.92 | 5.86 | 210.3 | 194.8 | 0 | 0 | 0.066 |
| Embodiment 2 | 20.81 | 6.23 | 225.1 | 203.5 | 0 | 0 | 0.052 |
| Embodiment 3 | 37.54 | 6.24 | 234.1 | 210.5 | 0 | 0 | 0.007 |
| Embodiment 4 | 31.45 | 6.73 | 239.2 | 213.3 | 0 | 0 | 0.005 |
| Embodiment 5 | 60.5 | 6.91 | 226.7 | 216.8 | 0 | 0 | 0.004 |
| Embodiment 6 | 23.67 | 6.98 | 228.4 | 207.1 | 0 | 0 | 0.004 |
| Embodiment 7 | 28.57 | 7.49 | 215.5 | 197.3 | 0 | 0 | 0.071 |
| Embodiment 8 | 22.85 | 7.86 | 229.2 | 206.8 | 0 | 0 | 0.059 |
| Embodiment 9 | 38.68 | 8.23 | 230.3 | 213.2 | 0 | 0 | 0.003 |
| Embodiment 10 | 33.21 | 8.36 | 237.6 | 215.3 | 0 | 0 | 0.005 |
| Embodiment 11 | 64.39 | 8.71 | 240.8 | 223.5 | 0 | 0 | 0.003 |
| Embodiment 12 | 35.76 | 8.94 | 247.6 | 228.4 | 0 | 0 | 0.004 |
| Comparative | 32.13 | 4.36 | 210.5 | 193.2 | 1 | 1 | 0.283 |
| Example | | | | | | | |

TABLE 2
Performance of composite current collector battery cells

| | Discharge | Internal | First | Capacity retention | | |
|---|---|---|---|---|---|---|
| | capacity | resistance | effect | rate-cycle number | | |
| No. | (mAh) | (mΩ) | (%) | 0.5 C | 1 C | 3 C |
| Embodiment 1 | 1298.67 | 13.50 | 91.50% | 1667 | 863 | 385 |
| Embodiment 2 | 1330.12 | 13.00 | 92.15% | 1687 | 899 | 369 |
| Embodiment 3 | 1320.56 | 12.76 | 92.26% | 1709 | 925 | 404 |
| Embodiment 4 | 1316.76 | 12.26 | 92.26% | 1754 | 951 | 423 |
| Embodiment 5 | 1312.56 | 12.00 | 93.10% | 1732 | 1093 | 458 |
| Embodiment 6 | 1325.67 | 11.57 | 93.05% | 1803 | 1117 | 456 |
| Embodiment 7 | 1295.56 | 13.60 | 91.51% | 1654 | 876 | 357 |
| Embodiment 8 | 1302.23 | 13.24 | 91.80% | 1678 | 849 | 385 |
| Embodiment 9 | 1312.45 | 13.13 | 92.07% | 1704 | 904 | 409 |
| Embodiment 10 | 1323.56 | 12.56 | 92.63% | 1765 | 931 | 392 |
| Embodiment 11 | 1299.45 | 12.30 | 92.35% | 1794 | 942 | 413 |
| Embodiment 12 | 1319.78 | 12.08 | 92.80% | 1776 | 1106 | 445 |
| Comparative | 1300.45 | 25.65 | 91.23% | / | / | / |
| Example | | | | | | |

It can be seen from the battery cell results in Tables 1 and 2 that Embodiments 1-12 of the present application have the ability to serve as a negative electrode current collector, which is a groundbreaking shift in the belief that aluminum (Al) cannot be used for the negative electrode.

The preferred embodiments of the present application are described in detail above, but the present application is not limited thereto. Within the scope of the technical conception of this application, the technical solution can be made into a variety of simple variations, including combining various technical features in any other suitable way. These simple variations and combinations should also be regarded as the content disclosed in this application and belong to the protection scope of this application.

What is claimed is:

1. A negative electrode current collector, comprising a barrier layer I, a conductive layer I, a polymer layer, a conductive layer II, and a barrier layer II in sequence.

2. The negative electrode current collector according to claim 1, wherein the materials of the barrier layer I and the barrier layer II are different from those of the conductive layer I and the conductive layer II.

3. The negative electrode current collector according to claim 1, wherein the materials of the barrier layer I and the barrier layer II are independently selected from a single metal I or an alloy I;
wherein, the single metal I is selected from one of a group consisted of aluminum, copper, nickel, iron, titanium, silver, gold, cobalt, chromium, molybdenum, and tungsten;
preferably, the single metal I is selected from one of a group consisted of aluminum, copper, nickel, iron, titanium, silver, gold, cobalt, chromium, molybdenum, and tungsten with a purity of ≥98 wt %, preferably 99-100 wt %;
wherein, the metal in the alloy I is selected from at least one of a group consisted of aluminum, copper, nickel, iron, titanium, silver, gold, cobalt, chromium, molybdenum, and tungsten, and further preferably, the alloy I is selected from at least one of a group consisted of copper-aluminum alloy, copper-nickel alloy, copper-zinc alloy, and copper-tin alloy;
preferably, thicknesses of the barrier layer I and the barrier layer II are independently selected from 1-1500 nm, preferably 0-1000 nm; and
preferably, bonding forces between the barrier layer I and the conductive layer I and between the conductive layer II and the barrier layer II are both ≥0.5 N/15 mm.

4. The negative electrode current collector according to claim 1, wherein the materials of the conductive layer I and the conductive layer II are independently selected from a single metal II or an alloy II;
wherein, the single metal II is selected from one of a group consisted of aluminum, copper, nickel, iron, titanium, silver, gold, cobalt, chromium, molybdenum, and tungsten;
preferably, the single metal II is selected from one of a group consisted of aluminum, copper, nickel, iron, titanium, silver, gold, cobalt, chromium, molybdenum, and tungsten with a purity of ≥98 wt %, preferably 99-100 wt %;
wherein, the metal in the alloy II is selected from at least one of a group consisted of aluminum, copper, nickel, iron, titanium, silver, gold, cobalt, chromium, molybdenum, tungsten, manganese, magnesium, and zinc, and the non-metal in the alloy II is selected from silicon and/or carbon; preferably, the alloy II is selected from at least one of a group consisted of aluminum-copper alloy, aluminum-manganese alloy, aluminum-silicon alloy, aluminum-magnesium alloy, aluminum-magnesium-silicon alloy, and aluminum-zinc alloy;
preferably, thicknesses of the conductive layer I and the conductive layer II are independently selected from 0.1-2 μm, preferably 0.2-1.5 μm;
preferably, bonding forces between the conductive layer I and the polymer layer and between the polymer layer and the conductive layer II are both ≥0.5 N/15 mm; and
preferably, a resistivity of the conductive layer I and the conductive layer II is ≤8 μΩ·cm.

5. The negative electrode current collector according to claim 1, wherein the material of the polymer layer is selected from at least one of a group consisted of acrylonitrile-butadiene-styrene copolymer, polyethylene terephthalate, polybutylene terephthalate, poly(p-phenylene terephthalamide), polyimide, polyamide, polyethylene, polystyrene, polyvinylidene fluoride, polyvinyl chloride, polytetrafluoroethylene, poly(p-phenylene-ethynylene), polypropylene, polycarbonate, polyoxymethylene, epoxy resin, and phenolic resin;
preferably, a tensile strength of the material of the polymer layer is ≥150 MPa, preferably 150-400 MPa;
preferably, a heat shrinkage rate of the material of the polymer layer after being treated at 150° C. for 30 minutes is ≤3%; and
preferably, a thickness of the polymer layer is 1-15 μm, preferably 1-10 μm.

6. The negative electrode current collector according to claim 1, wherein the negative electrode current collector further comprises an intermediate layer I and an intermediate layer II, wherein the intermediate layer I is arranged between the barrier layer I and the conductive layer I, and the intermediate layer II is arranged between the barrier layer II and the conductive layer II;
preferably, the materials of the intermediate layer I and the intermediate layer II are independently selected from a single metal III, an alloy III, an oxide semiconductor, or a conductive compound;
wherein, the single metal III is selected from one of a group consisted of Cu, Cr, Ta, Zn, Cd, In, Tl, Mn, Co, Mo, Fe, Sn, Ge, Bi, Sb, Re, Ti, V, Ni, Nb, and Tc, preferably one of a group consisted of Ti, V, Cr, Mn, Fe, Co, Ni, and Cu;
wherein, the metal in the alloy III is selected from at least one of a group consisted of Cu, Cr, Ta, Zn, Cd, In, Tl, Mn, Co, Mo, Fe, Sn, Ge, Bi, Sb, Re, Ti, V, Ni, Nb, and Tc, preferably at least one of a group consisted of Ti, V, Cr, Mn, Fe, Co, Ni, and Cu;
wherein, the oxide semiconductor is selected from at least one of a group consisted of Cu₂O, ZnO, SnO₂, Fe₂O₃, TiO₂, ZrO₂, Co₂O₃, WO₃, In₂O₃, Al₂O₃, and Fe₃O4;
wherein, the conductive compound is selected from at least one of a group consisted of TiB₂, TiC, TiN, ZrB₂, ZrC, ZrN, VB₂, VC, VN, NbB₂, NbC, NbN, TaB₂, TaC, CrB₂, Cr₃C₂, CrN, Mo₂C, Mo₂B₅, W₂B₅, WC, and LaB₆;
preferably, the intermediate layer I and the intermediate layer II are independently at least one of a group consisted of nickel, nickel-based alloy, copper-based alloy, and titanium nitride, preferably titanium nitride; and
preferably, thicknesses of the intermediate layer I and the intermediate layer II are independently 1-1000 nm, preferably 5-500 nm.

7. The negative electrode current collector according to claim 1, wherein the negative electrode current collector further comprises a bonding layer I and a bonding layer II; wherein the bonding layer I is arranged between the conductive layer I and the polymer layer, and the bonding layer II is arranged between the conductive layer II and the polymer layer;
preferably, materials of the bonding layer I and the bonding layer II are independently selected from at least one of a group consisted of ethyl cellulose, methylene succinic acid, styrene, carboxymethyl cellulose, guanidinoacetic acid, isocyanate, polyurethane, chitosan, polycaprolactone, and styrene butadiene latex, and optionally selected from at least one of a group consisted of nano-silicon dioxide, nano-aluminum oxide, and graphene oxide; and
preferably, thicknesses of the bonding layer I and the bonding layer II are independently selected from 0.2-3 μm, preferably 0.5-1 μm.

8. The negative electrode current collector according to claim 7, wherein the barrier layer I and the barrier layer II are made of the same material, and the conductive layer I and the conductive layer II are made of the same material;
preferably, the intermediate layer I and the intermediate layer II are made of the same material, and the bonding layer I and the bonding layer II are made of the same material.

9. A method for preparing a negative electrode current collector, wherein the method comprises: preparing a conductive layer I and a conductive layer II on the upper surface and the lower surface of a polymer layer respectively, and subsequently preparing a barrier layer I on the conductive layer I and a barrier layer II on the conductive layer II;
preferably, the method comprises: preparing, by evaporation, the conductive layer I and the conductive layer II on the upper surface and the lower surface of the polymer layer respectively, and subsequently preparing, by evaporation or sputtering, the barrier layer I on the conductive layer I and the barrier layer II on the conductive layer II;
preferably, before preparing, by evaporation, the conductive layer I and the conductive layer II on the upper surface and the lower surface of the polymer layer, prepare, by coating, a bonding layer I and a bonding layer II on the upper surface and the lower surface of the polymer layer respectively;
preferably, before preparing, by evaporation or sputtering, the barrier layer I and the barrier layer II on the conductive layer I and the conductive layer II, prepare, by magnetron sputtering, reactive sputtering, or activated reactive evaporation, an intermediate layer I on the conductive layer I and an intermediate layer II on the conductive layer II;
preferably, the evaporation is a vacuum evaporation, and operating conditions of the vacuum evaporation comprise: a vacuum degree higher than 10⁻³ Pa; a cold roller temperature of −25° C. to 35° C.; an ES distance≥50 mm; and an evaporation temperature≥800° C.;
preferably, operating conditions of the magnetron sputtering comprise: a vacuum degree higher than 10⁻³ Pa; a main roller temperature of −25° C. to +35° C.; a main roller travel speed of less than 20 m/min; and a sputtering power of less than 20 kW; and
preferably, operating conditions of the activated reaction evaporation comprise: a vacuum degree higher than 10⁻³ Pa; a cold roller temperature of −25° C. to 35° C.; an ES distance≥50 mm; and an evaporation temperature≥400° C.

10. A lithium-ion battery, comprising the negative electrode current collector according to claim 1.
